(19) United States
(12) Patent Application Publication
(10) Pub. No.: US 2015/0198635 A1
(43) Pub. Date: Jul. 16, 2015

(54) VOLTAGE DETECTION FOR LOW-POWER DEVICES

(71) Applicants: Bin Shao, Shanghai (CN); Yanfeng Lu, Shanghai (CN)

(72) Inventors: Bin Shao, Shanghai (CN); Yanfeng Lu, Shanghai (CN)

(21) Appl. No.: 14/178,931

(22) Filed: Feb. 12, 2014

Related U.S. Application Data
(63) Continuation of application No. PCT/CN2014/070710, filed on Jan. 16, 2014.

(51) Int. Cl. G01R 19/00; G01R 19/252

(52) U.S. Cl. CPC G01R 19/0084; G01R 19/252

(57) ABSTRACT

A device to sense voltage is provided. The device includes a first circuit operatively coupled to one or more nodes. The first circuit senses an electrical characteristic of each of the one or more nodes. The first circuit generates an adjustment signal based on the electrical characteristic sensed at each of the one or more nodes. A second circuit operatively receives a first voltage and a second voltage, the second circuit being configured to generate a third voltage by scaling the second voltage. The second circuit generates a comparison signal based on a comparison of the first voltage and the third voltage.

### CLAIM OF PRIORITY

This application is a continuation under 35 U.S.C. §111(a) and claims benefit of priority to International Patent Application Serial No. PCT/CN2014/070710, filed on Jan. 16, 2014, which is hereby incorporated by reference herein in its entirety.

### TECHNICAL FIELD

This document pertains generally, but not by way of limitation, to voltage detection circuits.

### BACKGROUND

A power regulator can be used to generate an output voltage that tracks a reference (desired) voltage. For example, a switching regulator can include one or more switches that are turned on and off to control the charging of an inductor. The duty cycle and/or timing of the switches can control the voltage level of the regulated voltage. In order to accurately track the reference voltage, a power regulator can include, or be coupled with, a feedback compensator to sense the output voltage and to adjust the output voltage. Feedback compensators can include one or more loops. One example loop can include an outer voltage loop that senses the output voltage of the power regulator. Measurements of the regulator's output voltages (and, in some embodiments, the output current) are fed back to the feedback compensator via a sensing circuit. A control signal is generated for reducing the error between the output voltage and the reference voltage. For example, in the context of switching regulators, the feedback compensator can generate a pulse width modulation signal to control the switching regulator based on comparing the sensed output voltage and the desired reference voltage.

### OVERVIEW

The systems, methods, and devices of the invention each have several aspects, no single one of which is solely responsible for its desirable attributes. Without limiting the scope of this invention as expressed by the claims which follow, some features will now be discussed briefly. After considering this discussion, and particularly after reading the section titled “Detailed Description,” one will understand how the features of this invention provide advantages that include improving voltage sensing, such as, but is not limited to, for low-power regulators.

In one embodiment, a device to sense voltage is disclosed. The device comprises one or more nodes. The device further comprises a first circuit operatively coupled to the one or more nodes. The first circuit is configured to sense an electrical characteristic of each of the one or more nodes. The first circuit is configured to generate an adjustment signal based on the electrical characteristic sensed at each of the one or more nodes. The device further comprises a second circuit operatively coupled to the first circuit. The second circuit is configured receive a first voltage and a second voltage. The second circuit is configured to generate a third voltage by scaling the second voltage based on the adjustment signal. The second circuit is configured to generate a comparison signal based on a comparison of the first voltage and the third voltage.

In another embodiment, a method of sensing voltage is disclosed. The method comprises sensing, using a first circuit operatively coupled to one or more nodes, an electrical characteristic of each of the one or more nodes. The method further comprises generating, using the first circuit, an adjustment signal based on the electrical characteristic sensed at each of the one or more nodes. The method further comprises receiving, using a second circuit operatively coupled to the first circuit, a first voltage and a second voltage. The method further comprises generating, using the second circuit, a third voltage by scaling the second voltage based on the adjustment signal. The method further comprises generating, using the second circuit, a comparison signal based on a comparison of the first voltage and the third voltage.

In another embodiment, a device for sensing voltage is disclosed. The device comprises means for sensing an electrical characteristic of one or more nodes. The sensing means is configured to generate an adjustment signal based on the electrical characteristic sensed at the one or more nodes. The device further comprises means for receiving a first voltage and a second voltage. The receiving means is configured to generate a third voltage by scaling the second voltage based on the adjustment signal. The receiving means is configured to generate a comparison signal based on a comparison of the first voltage and the third voltage.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a schematic block diagram illustrating a voltage detection circuit including an integrated circuit and external resistors in accordance with various embodiments described herein.

FIG. 2 is a schematic block diagram illustrating an example embodiment of an adjustment circuit of a voltage detection circuit.

FIG. 3 is a schematic block diagram illustrating an example embodiment of an adjustment circuit of a voltage detection circuit.

FIG. 4 is a timing diagram illustrating an example switching operation of the adjustment circuit of FIG. 3.

FIG. 5 is a schematic circuit diagram illustrating an example embodiment of a programmable voltage comparator of a voltage detection circuit.

FIG. 6 is a schematic block diagram illustrating another example embodiment of a programmable voltage comparator of a voltage detection circuit.

FIG. 7A is a schematic circuit diagram illustrating a first switching state of an example embodiment of a programmable voltage comparator of FIG. 6.

FIG. 7B is a schematic circuit diagram illustrating a second switching state of the example embodiment of a programmable voltage comparator of FIG. 7A.

### DETAILED DESCRIPTION

The following detailed description of embodiments presents various descriptions of specific embodiments of the invention. However, the invention can be embodied in a multitude of different ways as defined and covered by the claims. In this description, reference is made to the drawings where like reference characters may indicate identical or functionally similar elements.

Sensing circuits can receive an output voltage V_{OUT} to monitor against a threshold Vₜₕ. An integrated circuit containing the sensing circuit may include one or more pins that can be used to directly or indirectly set the threshold Vth. For example, some conventional sensing circuits can include a V_{OUT} pin, a V_{SNS} pin, and a comparator for comparing the output voltage at the V_{SNS} pin against a fixed reference voltage V_{ref}. The V_{OUT} pin provides the output voltage V_{OUT} to be monitored. To set the threshold value Vₜₕ, an external voltage divider can be coupled to the V_{OUT} pin to provide the V_{SNS} pin a scaled output voltage. One example voltage divider includes an external resistor R₁ coupled to the V_{OUT} pin and a resistor R₂ connected in between the resistor R₁ and ground, and the node between the external resistors R₁ and R₂ is connected to the V_{SNS} pin. Accordingly, the comparator tests the following condition:

$$\frac{{R}_{2}}{{R}_{1} + {R}_{2}} {V}_{OUT} > {V}_{ref} \qquad ( Eq . 1 )$$

Based on Equation 1, the threshold Vₜₕ can be approximated by the following equation:

$${V}_{th} = \frac{{R}_{2} + {R}_{1}}{{R}_{2}} {V}_{ref} \qquad ( Eq . 2 )$$

In certain systems, the output voltage V_{OUT} is about 3.3 volts (V). If the total resistance of an external voltage divider is about 20 kilohms (kΩ), the external voltage divider consumes a DC quiescent current of about 165 microamps (μA). Such a level of current consumption by the sensing circuit may be acceptable for certain applications, such as voltage regulators with an output current target greater than about 100 mA. However, in other applications, this level of DC quiescent current is unacceptably large. For example, some example ultra-low powers regulators may have a target load current in the range of about 10-100 μA. These ultra-low power regulators do not have sufficient current headroom to supply the DC quiescent current of the external voltage divider having 20 kΩ of resistance.

To reduce the DC quiescent current of the external voltage divider, larger external resistors may be used. However, using large external resistors, such as resistors larger than about 10 MΩ, may make it difficult to obtain sufficient accuracy of the ratio of the resistors. Another concern is that the noise to signal ratio may become unacceptable when using external resistors greater than about 10 MΩ. Yet another concern is that even using 20 MSΩ of external resistance results in a DC quiescent current of about 1.65 μA, which can be too high for some ultra-low power regulators with a target output current of about 1 μA, or even about 500 nA. Thus, there is a need for improved voltage sensing circuits.

Embodiments are described in the context of systems and methods for sensing an output voltage of power regulators, but will be applicable to other types of circuits that perform voltage sensing, such as, but is not limited to, electronics and circuits associated with low-power/ultra-low-power applications, including circuits related to power harvesting, mobile devices, sensors, detectors, and transducers. In one embodiment, the system includes an integrated circuit that uses an internal circuit (for example, an internal voltage divider) for comparing the sensed voltage to a reference voltage. Because the internal circuit is fabricated as part of integrated circuit, the internal circuit can be implemented to provide large resistances accurately (e.g., as compared to external resistors). In addition, the internal circuit, being disposed within a protected environment provided by the integrated circuit, can exhibit improved immunity to external noise. As a result, the resistance provided by the internal circuit can be increased such that the internal circuit produces low DC quiescent current and, in turn, consumes low power, while accurately sensing the output voltage V_{OUT}. Moreover, the internal circuit can be programmable to dynamically adjust, for example, the reference level and various thresholds (e.g., a lower threshold and/or an upper threshold).

In one aspect of certain embodiments described herein, the integrated circuit may scale the sensed output voltage using power-efficient circuits. Because the scaling is implemented internally on the integrated circuit, a wide range of circuits can be chosen to implement the scaling function. In contrast, external circuits are limited by, for example, complexity since external electrical parts can be large and the external circuit may be designed and assembled by the user. As a result, the simple external circuits (e.g., voltage divider type circuits) that can be used are relatively inefficient. Thus, some embodiments described herein improve efficiency and/or reduce chip size.

In another specific embodiment, an integrated circuit containing the voltage sensing circuit can include one or more pins for setting the threshold Vₜₕ and or other parameters. External resistors can be coupled to the pins to effectuate the desired settings. However, DC current may cease to flow through these external resistors during some duration of operation. In other words, the integrated circuit may conduct current through the pins during a duration in which the settings are to be determined. During this duration, the voltages at the pins are determined and latched. Thereafter, for another duration, the integrated circuit can cease flowing current through the pins. For example, the integrated circuit may flow current through the “setting” pins during an initialization period and then stop flowing current during a voltage sensing period. In that way, power consumption of the external resistors can be reduced. Moreover, when the integrated circuit is not checking the settings indicated by the “setting” pins, theses pins can be configured to perform other functions during those periods of time. Accordingly, the number of physical pins of the chip can be reduced, and the chip size and cost can therefore be reduced.

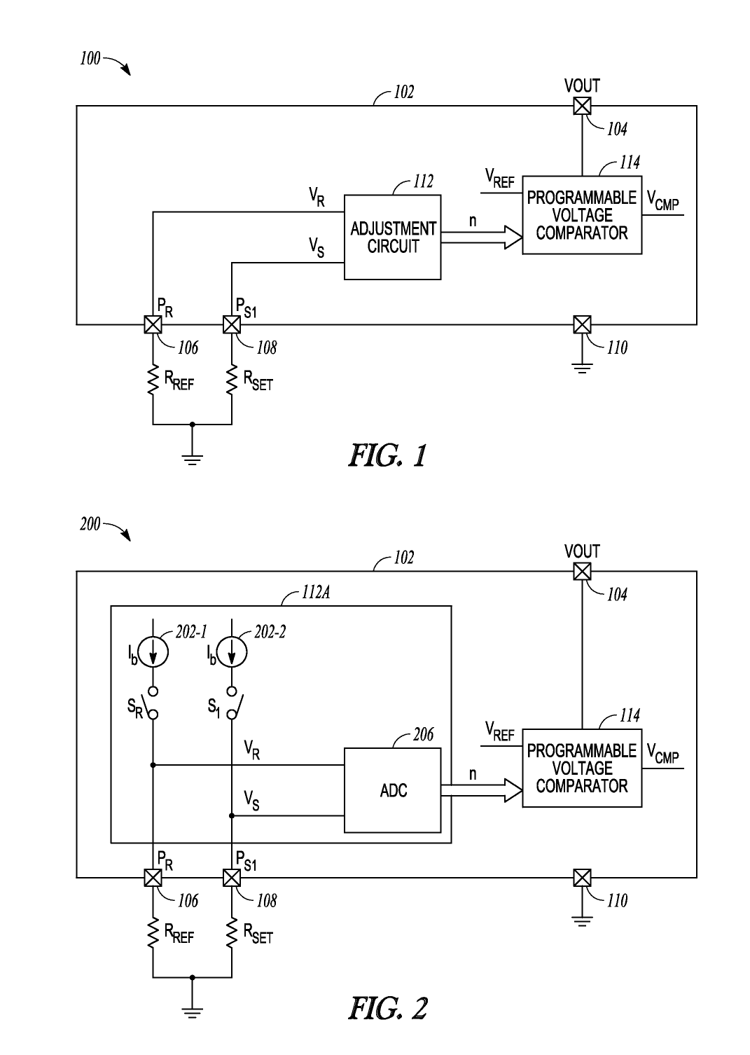

To further illustrate, FIG. 1 is a schematic block diagram illustrating a voltage detection circuit 100 including an integrated circuit 102 and external resistors R_{ref}, Rₛₑₜ in accordance with various embodiments described herein. The integrated circuit 102 includes one or more pins 104, 106, 108, 110, an adjustment circuit 112, and a programmable voltage comparator 114.

The integrated circuit 102 is configured to receive the output voltage V_{OUT}, the reference voltage V_{REF}, and the setting voltages V_{R}, V_{S} as inputs and to generate the comparison signal V_{CMP}. For example, the illustrated integrated circuit 102 is configured to generate the comparison signal V_{CMP} by comparing the output voltage V_{OUT} sensed at the pin 104 with the reference voltage V_{ref} in accordance with the settings indicated by the voltage V_{R} and V_{S} sensed at the pins 106, 108. The output voltage V_{OUT} can correspond to a voltage to be monitored. The output voltage V_{OUT} can be supplied by a circuit (e.g., a power regulator (not shown)) that is internal or external to the integrated circuit 102.

The integrated circuit 102 can correspond to a monolithic integrated circuit or chip. The pins 104, 106, 108, 110 of the integrated circuit 102 are described by example as pins, which can correspond to physical electrical contacts of the integrated circuit or chip 102. It will be appreciated, however, that the pins 104, 106, 108, 110 can also correspond to a pad, a port, a lead, a terminal, a contact, a connector, or a like node of the integrated circuit 102.

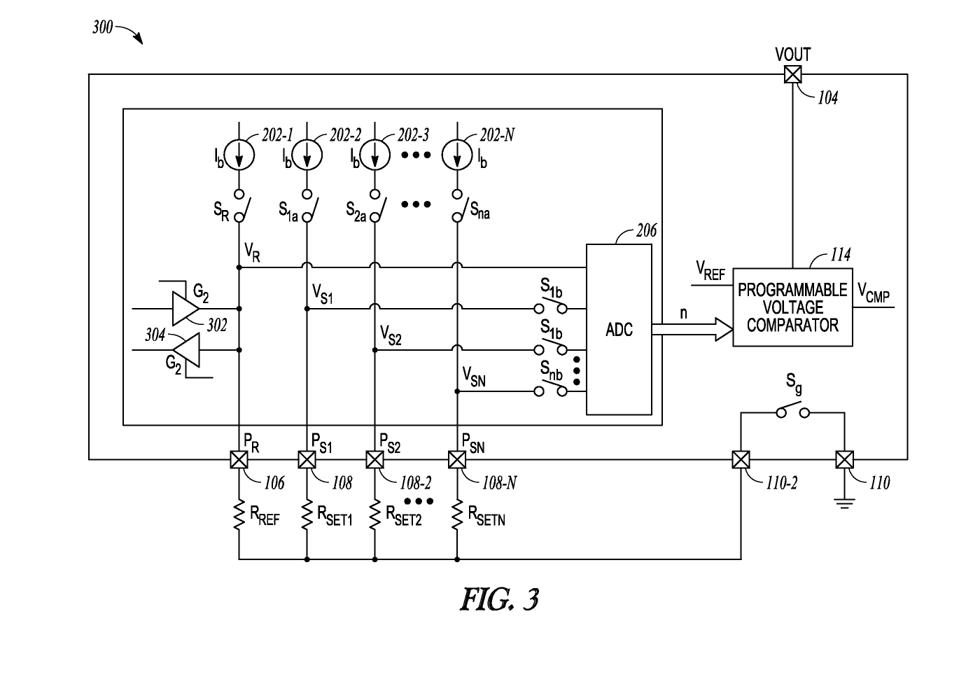

The pin 110 can be configured to connect to supply voltage, such as a ground node, and its function will be described in greater detail later in connection with FIG. 3.

The setting voltages V_{R} and V_{S} can correspond to voltages that indicate a desired setting of the voltage detection circuit 100. For example, a ratio of the setting voltage V_{R} and the setting voltage V_{S} can be used by the integrated circuit 102 to determine a voltage monitoring threshold Vₜₕ. The voltage monitoring threshold Vₜₕ can be used in the generation of the comparison signal V_{CMP}. As stated, the integrated circuit 102 can generate the comparison signal V_{CMP} by comparing the output voltage V_{OUT} to the threshold Vₜₕ. In one embodiment, the integrated circuit 102 generates the comparison signal V_{CMP} as a HIGH value if the condition V_{OUT}>Vₜₕ is approximately satisfied; otherwise, the comparison signal V_{CMP} is generated as a LOW value. Accordingly, the resistances of the resistor R_{ref} and Rₛₑₜ can be selected to achieve the desired settings.

The adjustment circuit 112 of the integrated circuit 102 can be configured to receive the setting voltages V_{R} and V_{S} as inputs and to generate the adjustment signal n as an output. For example, the illustrated adjustment circuit 112 has a first input operatively coupled to the pin 106 and a second input operatively coupled to the pin 108. In operation, the adjustment circuit 112 can generate the adjustment signal n by sensing the voltages V_{R} and V_{S} generated at the pins 106, 108. In some embodiments, the adjustment circuit 112 is configured to conduct currents through the pins 106, 108 in order to generate voltages at the pins 106, 108 based on the setting resistors R_{ref}, Rₛₑₜ coupled to the pins 106, 108.

As stated, the settings voltages V_{R}, V_{S} can determine settings used in the comparison of the output voltage V_{OUT} and the reference voltage V_{ref}. Accordingly, the adjustment circuit 112 generates the adjustments signal n to effectuate the selected settings. As such, the adjustment circuit 112 can include logic that translate the setting voltages V_{R}, V_{S} to the adjustment signal n in a way that is effective for the selected settings. In other words, the logic acts as an interface between the sensed voltages and programmable voltage comparator 114. The adjustment circuit 112 will be described later in greater detail in connection with FIGS. 2 and 3.

The programmable voltage comparator 114 of the integrated circuit 102 can be configured to receive the output voltage V_{OUT}, the reference voltage V_{REF}, and the adjustment signal n as inputs and to generate the comparison signal V_{CMP} as an output. For example, the illustrated programmable voltage comparator 114 is operatively coupled to the pin 104 for receiving the output voltage V_{OUT}. Moreover, the illustrated programmable voltage comparator 114 is operatively coupled to the adjustment circuit 112 for receiving the adjustment signal n. The programmable voltage comparator 114 can receive the reference voltage V_{ref} from any appropriate internal or external circuit for providing a voltage signal. For example, the reference voltage V_{ref} can be provided via a pin of the integrated circuit 102. In one particular embodiment, the reference voltage V_{ref} corresponds the voltage V_{R} provided at the pin 106 and latched by the adjustment circuit (e.g., by an analog-to-digital converter). In another embodiment, the reference voltage V_{ref} is provided by a voltage reference circuit (not shown).

The comparison signal V_{CMP} can be generated by comparing the output voltage V_{OUT} and the reference voltage V_{ref} in accordance with the settings determined by the voltages V_{R} and V_{S}. One such setting influences a scaling of at least one of the output voltage V_{OUT} or the reference voltage V_{REF} to effectively set the threshold Vₜₕ. In one embodiment, the programmable voltage comparator 114 generates a scaled voltage of the output voltage V_{OUT} and generates the comparison signal V_{CMP} by comparing the reference voltage V_{ref} and the scaled voltage. The programmable voltage comparator 114 will be described in greater detail later in connection with FIGS. 5-7B

While the voltage detection circuit 100 was described above as sensing voltages at the pins 106, 108, it will be understood that other embodiments sense any other suitable electrical characteristics, such as currents, impedances, power, and the like.

FIG. 2 is a schematic block diagram illustrating an example embodiment of an adjustment circuit 112a of a voltage detection circuit 200. Elements common to FIGS. 1 and 2 share common reference indicia, and only differences between the Figures are described herein for the sake of brevity. The voltage detection circuit 200 includes the integrated circuit 102 and the external resistors R_{ref}, Rₛₑₜ. The integrated circuit 102 includes the one or more pins 104, 106, 108, 110, an adjustment circuit 112a, and the programmable voltage comparator 114.

The adjustment circuit 112a includes current sources 202-1, 202-2, switches S_{R}, S₁, and an analog-to-digital converter (ADC) 206. In the illustrated embodiment, the switch S_{R} has a first end operatively coupled to the current source 202-1 and a second end operatively coupled to the pin 106. The switch S₁ has a first end operatively coupled to the current source 202-2 and a second end operatively coupled to the pin 108. The current I_{b} can be selected to be about 10 uA, the R_{ref} can be selected to be about 100 kΩ, and Rₛₑₜ can be selected to be about 50 Ω. It will be appreciated that other values can be readily selected based on available power, desired settings of the detection circuit 200, and the like considerations.

The switches S_{R}, S₁ can include one or more mechanical devices, MEMs devices, and transistors, including insulated gate field-effect transistors, such as MOSFETs. However, it will be understood that a gate can be made from materials other than metals, such as polysilicon, and an insulation layer can be made out of materials other than silicon oxide, such as a high k dielectric. It will also be understood that the switches S_{R}, S₁ can have various structural types other than MOSFETs, including, but not limited to, BJT, JFET, IGFET, MESFET, pHEMT, HBT, and the like transistor structural types. Further, the switches S_{R}, S₁ can also have various polarities, such as N-channel, P-channel, NPN-type, and PNP-type; and can include various semiconductor materials, such as Si, SiC, GaAs, GaN, SiGe, and the like.

The illustrated ADC 206 has a first input operatively coupled to the second end of the switch SR, and a second input operatively coupled to the second end of the switch S1. In one embodiment, the ADC can correspond to a 10-bit ADC. However, it will be appreciated that the ADC 206 can use any number of bits based on resolution and range considerations.

In operation, the ADC 206 can be configured to sense the voltages V_{R}, V_{S} at the pins 106, 108. For example, during a setting sensing phase (e.g., an initialization phase) the switch S_{R}, S₁ can close and the currents I_{b} of the current sources 202-1, 202-2 can flow through the setting resistors R_{ref}, Rₛₑₜ and generate voltages V_{R}, V_{S}. The ADC 206 can sense the generated voltages V_{R}, V_{S} simultaneously or sequentially.

In addition, the ADC 206 can include logic circuitry for converting the sensed voltages V_{R}, V_{S} to the adjustment signal n. As one example, the adjustment circuit 112a can use the sensed voltages V_{R}, V_{S} to determine the adjustment signal n based on a ratio of the sensed voltages V_{R}, V_{S}. For example, the adjustment signal n can be determined from the following equation:

$$n = \frac{{V}_{S}}{{V}_{R}} N \qquad ( Eq . 3 )$$

In Equation 3, N can correspond to the maximum digital output of the ADC 206. For example, if the ADC 206 corresponds to a 10 bit ADC, then N is 1023.

The logic circuitry of the adjustment circuit 112a can generate the adjustment signal n in a format compatible with the programmable voltage comparator 114. For example, in one embodiment, the adjustment signal n can be a digital signal for adjusting a digitally control variable resistor element of the programmable voltage comparator 114. Moreover, a digitally control variable resistor element may include a plurality (e.g., N) of resistive elements that can be activated dynamically by the adjustment signal n. Accordingly, the logic circuitry of the ADC 206 may include a thermodecoder circuit to convert a binary code (for example, according to Equation 3) to a thermometer code. In turn, the thermometer-code representation of the adjustment signal n can be used to activate a selected number of the resistive elements of the programmable voltage comparator 114 in order to adjust the threshold voltage Vₜₕ of the programmable voltage comparator 114.

In one embodiment, the adjustment circuit 112a is configured to sense the voltages V_{R}, V_{S} (or equivalently the resistors R_{ref}, Rₛₑₜ) for a duration in response to an activation event, such a control signal, initialization, or a periodic setting-sensing routine. During the duration, the switches S_{R}, S₁ close so that current I_{b} flows through the resistors R_{ref}, Rₛₑₜ. The sensed voltages V_{R}, V_{S} and/or the adjustment signal n can be latched. After latching, the switches S_{R}, S₁ can open so that current I_{b} no longer flows through the resistors R_{ref}, Rₛₑₜ. Advantageously, when the switches S_{R}, S₁ are open, there is no substantial quiescent DC current flowing through the external resistors R_{ref}, Rₛₑₜ. Accordingly, the adjustment circuit 112a can improve system efficiency.

FIG. 3 is a schematic block diagram illustrating an example embodiment of an adjustment circuit 112b of a voltage detection circuit 300. Elements common to FIGS. 2 and 3 share common reference indicia, and only differences between the Figures are described herein for the sake of brevity. The voltage detection circuit 300 includes the integrated circuit 102 and the external resistors R_{ref}, Rₛₑₜ₁, . . . , Rₛₑₜₙ. The integrated circuit 102 includes the one or more pins 104, 106, 108, 108-2, . . . , 108-n, 110, 110-2, the adjustment circuit 112b, the programmable voltage comparator 114, and the switch S_{g}. The adjustment circuit 112b includes current sources 202-1, 202-2, 202-3, . . . , 202-n, switches S_{R}, S₁ₐ, S₂ₐ, . . . , Sₙₐ, S_{1b}, S_{2b}, . . . , S_{nb}, the ADC 206, and line buffers G₁, G₂.

The pins 108, 108-2, . . . , 108-n can be used to set one or more settings based on the voltages generated at the pins 108, 108-2, . . . , 108-n. For example, the pins 108, 108-2, . . . , 108-n are each configured to couple to a first end of a respective external (settings) resistor R_{ref}, Rₛₑₜ₁, . . . , Rₛₑₜₙ. Additionally, each of the external resistors R_{ref}, Rₛₑₜ₁, . . . , Rₛₑₜₙ has a second end that is operatively coupled to the pin 110-2. Furthermore, the pin 110-2 is selectively coupled to ground via the switch S_{g} and the pin 110. Accordingly, if a current I_{b} is applied to one of the pins 108, 108-2, . . . , 108-n and if the switch S_{g} is closed, then the current I_{b} can flow through the respective resistor and thereby generates a voltage at the corresponding pin.

In the illustrated embodiment of the adjustment circuit 112b, the switch S_{R} has a first end operatively coupled to the current source 202-1 and a second end operatively coupled to the pin 106. The switch S₁ₐ has a first end operatively coupled to the current source 202-2 and a second end operatively coupled to the pin 108. The switch S₂ₐ has a first end operatively coupled to the current source 202-3 and a second end operatively coupled to the pin 108-2. The switch Sₙₐ has a first end operatively coupled to the current source 202-n and a second end operatively coupled to the pin 108-n. In addition, the ADC 206 has a first input coupled to the pin 106, a second input selectively coupled to the pin 108 via the switch S_{1b}, a third input selectively coupled to the pin 108-2 via the switch S_{2b}, and an n-th input selectively coupled to the pin 108-n via the switch S_{nb}.

In operation, the adjustment circuit 112b can be configured to sense the voltages of the pins 106, 108, 108-2, . . . , 108n in a manner similar to the sensing described above in connection with FIG. 2. In addition, the switch S_{g} should be closed in order for the currents I_{b} of the current sources 202-1, . . . , 202-n to flow through the settings resistors R_{ref}, Rₛₑₜ₁, . . . , Rₛₑₜₙ. Additionally, the corresponding switch S_{1b}, . . . , S_{nb} should also be closed in order for the corresponding input of the ADC 206 to be coupled to the corresponding pin 108, 108-2, . . . , 108-n.

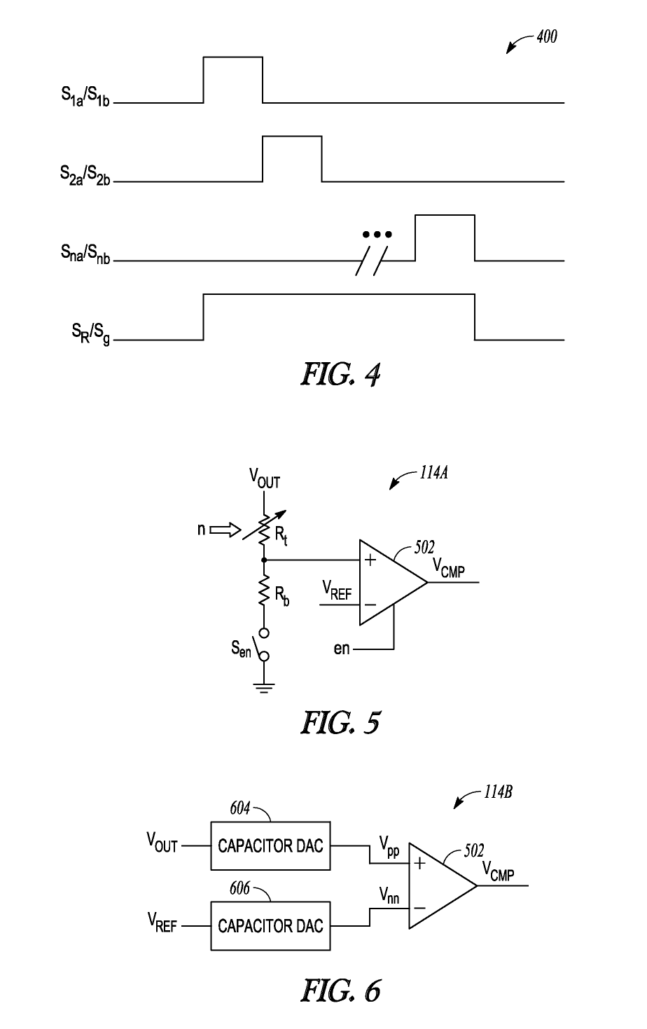

In one embodiment, the ADC 206 is configured to sense the voltages V_{S1}, V_{S2}, . . . , V_{Sn} sequentially. For example, each of the pairs of switches (S₁ₐ, S1b), (S₂ₐ, S2b), . . . , (Sₙₐ, Snb) can be closed for a separate duration. Additionally or alternatively, the switches S_{R}, S_{g} can remain closed during the sensing process. In that way, each of the voltages V_{S1}, V_{S2}, . . . , V_{Sn} can be combined with the voltage V_{R} (e.g., combined by taking a ratio). A timing diagram of an example embodiment is described later in greater detail in connection with FIG. 4.

The pins 108, 108-2, . . . , 108-n can provide a way to control a plurality of settings, such as, but not limited to an overvoltage threshold, undervoltage threshold, a power condition, and a hysteresis of a threshold. For example, each of the pins 108-2, . . . , 108-n can be associated with a setting. The ADC 206 can be configured to detect each value (e.g., via the pin voltages) one by one, as stated, and latch the digital code after each conversion.

In some embodiments, if the adjustment circuit 112 is not sensing the voltages at the pins 106, 108, 108-2, . . . , 108-n, then those pins can be used for other functions. For example, one or more of the pins can receive input control signals or provide output signals if the corresponding switches S_{R}, S₁ₐ, S₂ₐ, . . . , Sₙₐ, S_{1b}, S_{2b}, . . . , S_{nb} and the switch S_{g} are open. In addition, the illustrated adjustment circuit 112b includes the line buffer G₁ 302 for providing an output signal and the line buffer G₂ 304 for receiving an input signal at the pin 106.

FIG. 4 is a timing diagram 400 illustrating an example switching operation of the adjustment circuit 112b of FIG. 3. The timing diagram 400 illustrates the switching states (close/open) as a function of time. The switching state is represented by the vertical axis. A HIGH value corresponds to a close state and a LOW value corresponds to an open state. Time is represented by the horizontal axis. During a first duration, switches S₁ₐ, S_{R}, Sg are closed. Accordingly, currents I_{b} are allowed to flow through the external settings resistors R_{ref}, Rₛₑₜ₁ and generate voltages V_{R}, V_{S1}. In addition, switch S_{1b} is also closed, thereby coupling the ADC 206 to the pin 108. As a result, the ADC 206 can be configured to sense the voltages V_{R}, V_{S1} with the ADC 206. Because switches S₂ₐ, . . . , Sₙₐ are open, currents I_{b} do not flow through the other external resistors. Also, because the switches S_{2b}, . . . , S_{nb} are open, the ADC 206 does not sense the voltages at the remaining pins.

During a second duration, switches S₂ₐ, S_{R}, S_{g} are closed. Accordingly, currents I_{b} are allowed to flow through the external settings resistors R_{ref}, Rₛₑₜ₂ and generate voltages V_{R}, V_{S2}. In addition, switch S_{2b} is also closed, thereby coupling the ADC 206 to the pin 108-2. As a result, the ADC 206 can be configured to sense the voltages V_{R}, V_{S2}. Because switches S₁ₐ, S₁ₐ, . . . , Sₙₐ are open, currents I_{b} do not flow through the other external resistors. Also, because the switches S_{1b}, S_{3b}, . . . , S_{nb} are open, the ADC 206 does not sense the voltages at the remaining pins.

During a subsequent duration, switches Sₙₐ, S_{R}, S_{g} are closed. Accordingly, currents I_{b} are allowed to flow through the external settings resistors R_{ref}, Rₛₑₜₙ and generate voltages V_{R}, V_{Sn}. In addition, switch S_{nb} is also closed, thereby coupling the ADC 206 to the pin 108-n. As a result, the ADC 206 can be configured to sense the voltages V_{R}, V_{Sn}. Because switches S₁ₐ, . . . , S(n−1)a are open, currents I_{b} do not flow through the other external resistors. Also, because the switches S_{1b}, . . . , S_{(n-1)b} are open, the ADC 206 does not sense the voltages at the remaining pins.

FIG. 5 is a schematic circuit diagram illustrating an example embodiment of a programmable voltage comparator 114a of a voltage detection circuit 100. The programmable voltage comparator includes a tunable resistor Rₜ, a base resistor R_{b}, a switch Sₑₙ, and a comparator 502.

The programmable voltage comparator 114a is configured to receive the output voltage V_{OUT} and the reference voltage V_{ref} as inputs, to receive the adjustment signal n and an enable signal en as controls, and to generate the comparison signal V_{CMP} as an output. For example, the illustrated programmable voltage comparator 114a is configured to receive the output voltage V_{OUT} with a first end of the tunable resistor Rₜ. The second end of the tunable resistor Rₜ is coupled to the non-inverting input of the comparator 502 and to a first end of the base resistor R_{b}. A second end of the base resistor R_{b} is operatively coupled to ground via the switch Sₑₙ. The internal resistors Rₜ and R_{b} form a voltage divider and generate a voltage V₃ at the non-inverting input of the comparator 502. In addition, the inverting input of the comparator 502 is configured to receive the reference voltage V_{ref}. The tunable resistor Rₜ is configured to receive the adjustment signal n to determine a variable resistance of the tunable resistor Rₜ. The switch Sₑₙ is configured to receive the enable signal en to selectively open and close, and the comparator 502 is also configured to receive the enable signal en to selectively activate and deactivate.

The tunable resistor Rₜ can be configured to adjust a resistance based on the adjustment signal n. For example, the tunable resistor can correspond to a digital or analog potentiometer, a voltage controlled transistor, or the like variably controlled resistive element. Additionally or alternatively, the tunable Rₜ can comprise a plurality of resistive elements that can be selectively switched into the circuit to provide an addition resistance.

In one embodiment, the resistors Rₜ and R_{b} are internal resistors of the integrated circuit of the voltage detection circuit. Internal resistors can be made accurately, for example, by utilizing semiconductor processing and fabrication technologies. Moreover, material of the integrated circuit packaging can encapsulate the resistors Rₜ, R_{b} and thereby attenuates some sources of external noise, such as electromagnetic interference. Accordingly, large resistances, such as resistances of about 100 MΩ or greater, can be used effectively. Such large resistances can result in low DC quiescent current, for example, of about 50 nA or less.

In operation, if the switch Sₑₙ is closed and the comparator 502 is enabled, then the internal resistors Rₜ and R_{b} form a voltage divider. As such, the voltage divider generates a scaled version of the output voltage V_{OUT} at the non-inverting input of the comparator 502. The comparator 502 is configured to generate the comparison signal V_{CMP} by comparing the scaled version of the output voltage V_{OUT} to the reference voltage V_{ref}. For example, in the illustrated embodiment of FIG. 5, the voltage divider formed by Rₜ and R_{b} generates a voltage V₃ based upon the output voltage V_{OUT}. The voltage V₃ can be approximated by the following equation:

$${V}_{3} \approx \frac{{R}_{b}}{{R}_{b} + {R}_{t}} {V}_{OUT} . \qquad ( Eqn . 4 )$$

The voltage V₃ is provided to the comparator 502 at the non-inverting input of the comparator 502. Additionally, the comparator 502 receives the reference voltage V_{REF} at its inverting input. The comparator 502 can generate the comparison signal V_{CMP} based upon its inputs V₃ and V_{ref}. In particular, the comparator 502 can assert the comparison signal V_{CMP} HIGH if V₃>V_{ref}, and LOW otherwise. In view of Equation 4, the comparator 502 asserts the comparison signal V_{CMP} HIGH if the following inequality is satisfied:

$${V}_{OUT} > \underbrace{\frac{{R}_{b} + {R}_{t}}{{R}_{b}} {V}_{ref}}_{{V}_{th}} . \qquad ( Eqn . 5 )$$

In Equation 5, the right hand side of the inequality can correspond to the threshold Vₜₕ to which the output voltage V_{OUT} is compared. Moreover, as Equation 5 shows, the threshold voltage Vₜₕ changes as the resistances R_{b} and Rₜ change.

As an illustrative example, in one embodiment, the reference voltage V_{ref} is about 1.2 V and the maximum expected output voltage V_{OUTM} to be monitored is about 6 V. Thus, the ratio m of V_{OUTM} to V_{ref} corresponds to about m=5. The maximum code of the ADC of FIG. 2 is N. Accordingly, the threshold Vₜₕ of the output voltage V_{OUT} can be given based on the following example equation:

$${V}_{th} = \frac{n}{N} \times m \times {V}_{ref} . \qquad ( Eqn . 6 )$$

In accordance with Equation 6, the threshold voltage Vₜₕ can be selected from a range of about 0 V to about V_{OUTM} based on the adjustment signal n. For example, if the adjustment signal n is selected to be 0, then Equation 6 indicates that the threshold Vₜₕ=0. In addition, if the adjustment signal n is selected to be the maximum code N, then Equation 6 indicates that the threshold Vₜₕ=V_{OUTM}. It will be appreciated by one skilled in the art that other suitable mappings can be selected in addition to the mapping given in accordance with Equation 6. Some example mappings can provide threshold voltages Vₜₕ from a lower bound V_{OUTM} to an upper bound V_{OUTM}, wherein one or both of the bounds can be negative and/or positive bounds.

Referring back to FIG. 5, the resistors R_{b} and Rₜ can be selected and/or adjusted based on the adjustment signal n to effectuate the desired threshold Vₜₕ. For example, the right-hand-side of Equation 5 can be equated with the right-hand-side of Equation 6 to determine the values of the resistors R_{b} and Rₜ based upon the adjustment signal n. For example, if the base resistor R_{b} of the resistor voltage divider is fixed, then the tunable resistor Rₜ of the resistor voltage divider can be adjusted according to the following equation:

$${R}_{t} = {R}_{b} ( m \frac{n}{N} - 1 ) . \qquad ( Eqn . 7 a )$$

Equation 7a can be derived by equating the right-hand-sides of Equations 5 and 6 and solving for Rₜ. Equation 7a can be rewritten in terms of the setting voltages V_{R} and V_{S} using Equation 3:

$${R}_{t} = {R}_{b} ( m \frac{{V}_{S}}{{V}_{R}} - 1 ) . \qquad ( Eqn . 7 b )$$

In accordance with Equations 7a and 7b, the tunable resistor Rₜ can be changed based at least on the voltages V_{S} and V_{R}. For example, the tunable resistor Rₜ can be changed to determine the threshold voltage Vₜₕ based upon a ratio of the setting voltages V_{S} and V_{R}. In particular, the adjustment signal n can be based upon a ratio of V_{S}/V_{R}, wherein the tunable resistor Rₜ can be based upon the adjustment signal n (for example, Rₜ can be proportional to a ratio of n/N).

Moreover, substitution of the expressions for Rₜ of Equation 7a into Equation 5 yields the following inequality:

$${V}_{OUT} > m \frac{n}{N} {V}_{ref} . \qquad ( Eqn . 8 a )$$

The comparator 502 is configured to assert the comparison signal V_{CMP} HIGH if the inequality of Equation 8a is satisfied. Furthermore, by using Equation 3, Equation 8a can be rewritten in terms of the setting voltages V_{R} and V_{S}:

$${V}_{OUT} > m \frac{{V}_{S}}{{V}_{R}} {V}_{ref} . \qquad ( Eqn . 8 b )$$

In turn, Equation 8b can be rewritten to express the condition on V_{OUT} expressed in Equation 8b as a condition on a ratio of the V_{OUT} and V_{ref}:

$$\frac{{V}_{OUT}}{{V}_{ref}} > m \frac{{V}_{S}}{{V}_{R}} . \qquad ( Eqn . 8 c )$$

Equation 8c shows that the comparator 502 is configured to assert the comparison signal V_{CMP} HIGH if the ratio V_{OUT}/V_{ref} is greater than a value that is proportional to the ratio V_{S}/V_{R}. As a result, it can be seen that the comparison signal V_{CMP} provides an indication of whether the output voltage V_{OUT} and the reference voltage V_{ref} have a ratio that substantially matches the ratio V_{S}/V_{R} scaled by a factor m. In the case of Equation 8c, the factor m is based on a ratio of the upper bound V_{OUTM} of the output voltage V_{OUT} to be monitored and the reference voltage V_{ref}.

Accordingly, in operation, one can set the threshold voltage Vₜₕ and other settings by generating the setting voltages V_{R} and V_{S} by using comparatively small resistors (e.g., as compared to Rₜ and R_{b}) and/or using comparatively large currents (e.g., as compared to the current flowing through Rₜ and R_{b}). The setting voltages V_{R} and V_{S}, can be latched and then the currents I_{b} terminated in order to reduce power consumption. Later the latched setting voltages V_{S}, V_{R} can used to determine the threshold voltage Vₜₕ in a circuit (e.g., the programmable voltage comparator 114) having larger resistors that draw less current and that are packaged in a noise resistant housing (e.g., the IC package). For example, as stated, the threshold voltage Vₜₕ can be based upon the ratio V_{S}/V_{R} and based upon selecting the internal resistors Rₜ and R_{b}.

In one aspect, the programmable voltage comparator 114a can further reduce power consumption by disabling portions of the circuit when that portion is not functioning. For example, the enable signal en can be used to disable the comparator 502 and to open the switch Sₑₙ to attenuate DC quiescent current if the programmable voltage comparator 114b is not in use.

FIG. 6 is a schematic block diagram illustrating another example embodiment of a programmable voltage comparator 114b of a voltage detection circuit 100. The programmable voltage comparator 114a includes a capacitor DAC (or “switched capacitor circuit”) 604, a capacitor DAC 606, and a comparator 502.

The capacitor DAC 604 is configured to receive the output voltage V_{OUT} as an input and to generate a voltage Vpp as an output. In the illustrated embodiment, the capacitor DAC 604 has an output operatively coupled to the non-inverting input of the comparator 502. In operation, the capacitor DAC 604 can be configured to generate the voltage Vpp at the non-inverting input by switching one or more capacitors to distribute the output voltage V_{OUT} in a way that generates a scaled version of the output voltage V_{OUT.} Capacitor DACs can have comparatively less power consumption than voltage dividers.

The capacitor DAC 606 is configured to receive the reference voltage V_{ref} as an input and to generate a voltage Vnn as an output. In the illustrated embodiment, the capacitor DAC 606 has an output operatively coupled to the inverting input of the comparator 502. In operation, the capacitor DAC 606 can be configured to generate the voltage Vnn at the inverting input by switching one or more capacitors to distribute the output voltage V_{ref} across the capacitors in a way that generates a scaled version of the reference voltage V_{OUT}.

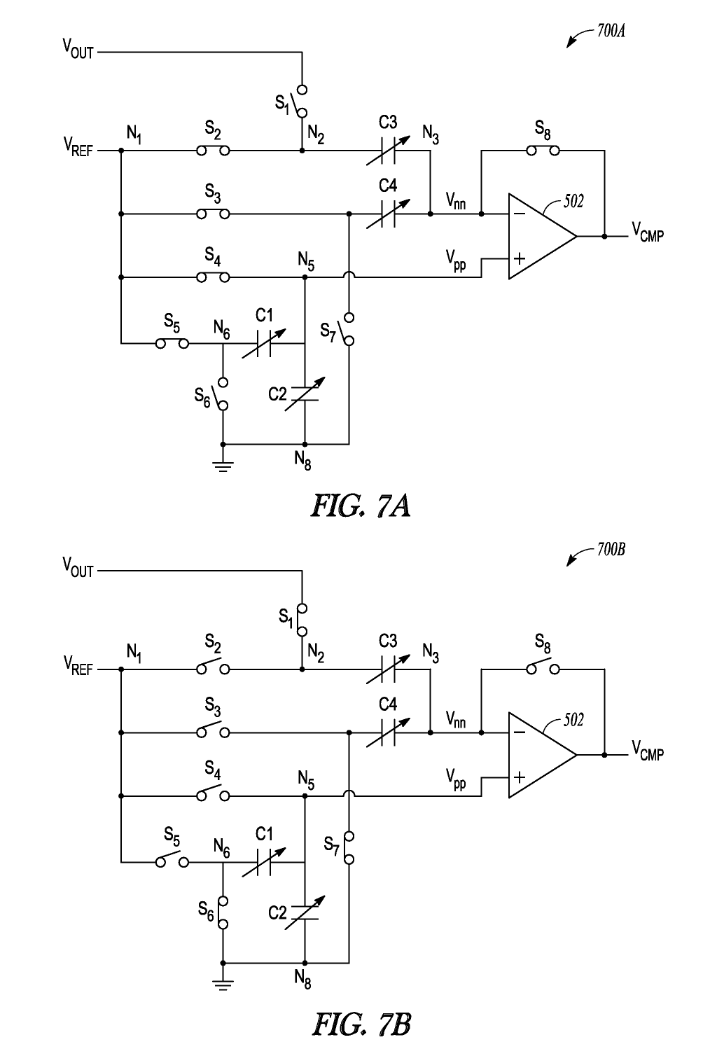

In some embodiments, the capacitor DAC 604 can be configured to sample the value of the output voltage V_{OUT} during a first duration. Additionally, the capacitor DAC 606 can be configured to sample the value of the reference voltage V_{ref} during a second duration. After the sampling of the second duration, the comparator 502 compares the voltages at its inputs. The programmable voltage comparator 114b is described in greater detail in connection with FIGS. 7A and 7B.

FIG. 7A is a schematic circuit diagram illustrating a first switching state of an example embodiment of a programmable voltage comparator 700a of FIG. 6. The programmable voltage comparator 700a includes capacitors C₁, C₂, C₃, C₄, switches S₁-S₈, and a comparator 502. The state of the switching shown in FIG. 7A corresponds to a phase for sampling the reference voltage V_{ref}.

In the illustrated embodiment, the first end of the switch S₁ is configured to receive the output voltage V_{OUT}. The second end of the switch S₁ is operatively coupled to the node N₂. The reference voltage V_{ref} can be received at node N₁. Each of the switches S₂, S₃, S₄, S₅ has a first end operatively coupled to the first node N₁. The second end of switch S₂ is operatively coupled to node N₂. The second end of switch S₃ is operatively coupled to node N₄. The second end of switch S₄ is operatively coupled to node N₅. The second end of switch S₅ is operatively coupled to node N₆. The switch S₆ has a first end operatively coupled to the node N₆ and a second end operatively coupled to node N₈. The switch S₇ has a first end operatively coupled to the node N₄ and a second end operatively coupled to node N₈. The switch S₈ has a first end operatively coupled to the node N₃ and a second end operatively coupled to the output of the comparator 502. The capacitor C₁ has a first end operatively coupled to the node N₆ and a second end operatively coupled to the node N₅. The capacitor C₂ has a first end operatively coupled to the node N₅ and a second end operatively coupled to the node Ng. The capacitor C₃ has a first end operatively coupled to the node N₂ and a second end operatively coupled to the node N₃. The capacitor C₄ has a first end operatively coupled to the node N₄ and a second end operatively coupled to the node N₃. The comparator 502 has an inverting input operatively coupled to the node N₃, non-inverting input operatively coupled to the node N₅, and an output configured to provide the comparison signal V_{CMP}.

The capacitors C₁-C₄ can each be adjusted based on the adjustment signal n, for example, each of the capacitors can be configured to adjust a capacitance based on the indication from the adjustment signal.

As stated, the illustrated open-close state of the switches S₁-S₈ corresponds to the phase during which the programmable voltage comparator 700a samples the reference voltage V_{ref}. For example, the switches S₂-S₅ and S₈ are closed, and the switches S₁, S₆, S₇ are opened. As such, the output voltage V_{OUT} is disconnected from the capacitors C₁-C₄ and the comparator 502. Moreover, the ends of the capacitor C₁ are shorted and thus C₁ stores no charge. The feedback path formed by the closed switch S₈ causes the inverting input to be pulled to the non-inverting input voltage (e.g., the reference voltage V_{ref}). Thus, the capacitors C₃, C₄ are also shorted and store no charge. The capacitor C₂ is coupled between the reference voltage V_{ref} and ground and thus stores a charge such that the voltage across C₂ is about V_{ref}.

FIG. 7B is a schematic circuit diagram illustrating a second switching state of the example embodiment of a programmable voltage comparator 700b of FIG. 7A. Elements common to FIGS. 7A and 7B share common reference indicia, and only differences between the Figures are described herein for the sake of brevity. The programmable voltage comparator 700a includes capacitors C₁, C₂, C₃, C₃, switches S₁-S₈, and a comparator 502.

The illustrated switching state of the switches S₁-S₈ corresponds to a phase during which the programmable voltage comparator 700b compares the output voltage V_{OUT} and the reference voltage V_{ref}. For example, the switches S₂-S₅ and S₈ are switched open, and the switches S₁, S₆, S₇ switched close. As such, the charge of capacitor C₂ that was stored in the first phase (as discussed in connection with FIG. 7A) is distributed between the capacitors C₁ and C₂. For example, the voltage on the non-inverting input of the comparator 502 can be approximated by the following equation:

$${V}_{pp} \approx \frac{{C}_{2}}{{C}_{1} + {C}_{2}} {V}_{ref} \qquad ( Eqn . 9 )$$

In addition, the output voltage V_{OUT} provided to the capacitors C₃ and C₄. These two capacitors C₃, C₄ form a capacitor divider. As such, the voltage provided to the inverting input of the comparator 502 can be approximated by the following equation:

$$\begin{matrix}{V}_{nn} \approx \frac{{C}_{3}}{{C}_{3} + {C}_{4}} {V}_{OUT} & ( Eqn . 10 ) \\ {V}_{pp} \approx \frac{{C}_{2}}{{C}_{1} + {C}_{2}} {V}_{ref} & ( Eqn . 11 )\end{matrix}$$

The adjustment signal n can adjust the capacitances of the capacitors C₁-C₄ in order to change the threshold voltage Vₜₕ. For example, the capacitors can be selected based on the following equations:

$$\begin{matrix}{V}_{th} \approx \frac{{C}_{2}}{{C}_{3}} \frac{{C}_{3} + {C}_{4}}{{C}_{1} + {C}_{2}} {V}_{ref} & ( Eqn . 12 ) \\ {V}_{th} \approx m \times {V}_{ref} \times \frac{n}{N} & ( Eqn . 13 ) \\ \frac{{C}_{2}}{{C}_{3}} \frac{{C}_{3} + {C}_{4}}{{C}_{1} + {C}_{2}} \approx m \frac{n}{N} & ( Eqn . 14 )\end{matrix}$$

In Equation 14, the selection of the capacitors C₁-C₄ can be based on any suitable rule to achieve the desired threshold voltage Vₜₕ. For example, in one particular embodiment, the capacitors C₁ and C₂ can be selected to have about equal capacitances (e.g., C₁≈C₂); the capacitors C₃ and C₄ can be selected to have about equal capacitances (e.g., C₃≈C₄); and the ratio of C₂/C₃ can be selected in accordance with Equations 12-14 to effectuate a selected threshold voltage Vₜₕ.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A device to sense voltage, the device comprising:
one or more nodes;
a first circuit operatively coupled to the one or more nodes, the first circuit being configured to sense an electrical characteristic of each of the one or more nodes, the first circuit being configured to generate an adjustment signal based on the electrical characteristic sensed at each of the one or more nodes; and
a second circuit operatively coupled to the first circuit, the second circuit being configured receive a first voltage and a second voltage, the second circuit being configured to generate a third voltage by scaling the second voltage based on the adjustment signal, the second circuit being configured to generate a comparison signal based on a comparison of the first voltage and the third voltage.

2. The device of claim 1, further comprising a monolithic integrated circuit comprising the first circuit and the second circuit.

3. The device of claim 1, wherein the adjustment signal is based on a ratio of two voltages of the one or more nodes, the comparison signal indicative of whether the first and second voltages have a ratio substantial greater than a value proportional to the ratio of two voltages of the one or more nodes.

4. The device of claim 1, wherein the one or more nodes are configured to operatively couple to resistors, the first circuit being configured to sense voltages generated at the one or more nodes by currents conducted through the resistors operatively coupled to the one or more nodes.

5. The device of claim 4, wherein the first circuit comprises:
a first switch having a first end to receive a first current and a second end operatively coupled to a first node of the one or more nodes, the first switch configured to selectively close and to provide the first current to the first node; and
a second switch having a first end to receive a second current and a second end operatively coupled to a second node of the one or more nodes, the second switch configured to selectively close and to provide the second current to the second node.

6. The device of claim 5, wherein the first circuit further comprises an analog-to-digital converter (ADC) operatively coupled to the first and second nodes, the ADC being configured to sense the voltages at the first and second nodes and to generate a digital signal, the adjustment signal being based on the digital signal.

7. The device of claim 1, wherein the first circuit is configured to sense the electrical characteristics of each of the one or more nodes sequentially.

8. The device of claim 1, further comprising:
a switch having a first end operatively coupled to a first node of the one more nodes and having a second end operatively coupled to a second node of the one more nodes, the switch being configured to close during a first duration, the first circuit being configured to sense voltages at the one or more nodes during the first duration.

9. The device of claim 1, wherein the second circuit comprises a variable resistor configured to receive the second voltage and to generate the third voltage, the variable resistor providing a resistance based on the adjustment signal.

10. The device of claim 1, wherein the second circuit comprises:
a variable resistor having a first end configured to receive the second voltage and a second end configured to generate the third voltage based on the adjustment signal; and
a comparator having first and second inputs and an output, the first input being operatively coupled to the second end of the variable resistor, the second input being configured to receive the first voltage, the comparator being configured to generate the comparison signal at the output of the comparator.

11. The device of claim 1, wherein the second circuit includes a switched-capacitance circuit configured to scale the second voltage.

12. The device of claim 1, wherein the second circuit comprises:
a first switched-capacitor circuit having an input to receive the first voltage and having an output;
a second switched-capacitor circuit having an input to receive the second voltage and having an output; and
a comparator having a first input operatively coupled to the output of the first switched-capacitor circuit and a second input operatively coupled to the output of the second switched-capacitor circuit.

13. A method of sensing voltage, the method comprising:
sensing, using a first circuit operatively coupled to one or more nodes, an electrical characteristic of each of the one or more nodes;
generating, using the first circuit, an adjustment signal based on the electrical characteristic sensed at each of the one or more nodes;
receiving, using a second circuit operatively coupled to the first circuit, a first voltage and a second voltage;
generating, using the second circuit, a third voltage by scaling the second voltage based on the adjustment signal,
generating, using the second circuit, a comparison signal based on a comparison of the first voltage and the third voltage.

14. The method of claim 13, wherein the first circuit and the second circuit form at least a portion of a monolithic integrated circuit.

15. The method of claim 13, further comprising:
providing, using a first switch, a first current to a first node of the one or more nodes to generate a voltage at the first node; and
providing, using a second switch, a first current to a second node of the one or more nodes to generate a voltage at the second node,
wherein sensing the electrical characteristic includes sensing the voltages generated at the first and second node.

16. The method of claim 13, wherein the generating the third voltage comprises:
receiving, using a variable resistor of the second circuit, the second voltage; and
generating the third voltage using the variable resistor by providing a variable resistance based on the adjustment signal.

17. The method of claim 13, wherein the generating the third voltage comprises receiving the second voltage with a first end of a variable resistor, the variable resistor having a resistance based on the adjustment signal, wherein the generating the comparison signal includes receiving the first voltage and the third voltage at the inputs of a comparator and using the comparator to generate the comparison signal.

18. A device for sensing voltage, the device comprising:
means for sensing an electrical characteristic of one or more nodes, the sensing means being configured to generate an adjustment signal based on the electrical characteristic sensed at the one or more nodes; and
means for receiving a first voltage and a second voltage, the receiving means being configured to generate a third voltage by scaling the second voltage based on the adjustment signal, the receiving means being configured to generate a comparison signal based on a comparison of the first voltage and the third voltage.

19. The device of claim 18, wherein the sensing means is further configured to selectively provide a first current to a first node of the one or more nodes, the sensing means being further configured to selectively provide a second current to a second node of the one or more nodes.

20. The device of claim 18, wherein receiving the means is further configured to provide a variable resistance based on the adjustment signal, the third voltage being based on the variable resistance.
